(19) United States
(12) Patent Application Publication
(10) Pub. No.: US 2026/0068708 A1
(43) Pub. Date: Mar. 5, 2026

(54) SUBSTRATE STRUCTURE

(71) Applicant: Unimicron Technology Corp., Taoyuan City (TW)

(72) Inventors: Chin-Sheng Wang, Taoyuan City (TW); Cheng-Ta Ko, Taipei City (TW); Ra-Min Tain, Hsinchu County (TW); Chih-Kai Chan, Taoyuan City (TW)

(73) Assignee: Unimicron Technology Corp., Taoyuan City (TW)

(21) Appl. No.: 19/380,920

(22) Filed: Nov. 5, 2025

Related U.S. Application Data
(63) Continuation-in-part of application No. 19/309,529, filed on Aug. 25, 2025.
Application No. 19/309,529 is a continuation-in-part of application No. 19/023,397, filed on Jan. 16, 2025.
Application No. 19/023,397 is a continuation-in-part of application No. 18/677,924, filed on May 30, 2024.
(60) Provisional application No. 63/623,823, filed on Jan. 23, 2024.
(60) Provisional application No. 63/666,227, filed on Jun. 30, 2024.
(60) Provisional application No. 63/699,160, filed on Sep. 26, 2024.
(60) Provisional application No. 63/836,407, filed on Jul. 1, 2025.

(30) Foreign Application Priority Data
Apr. 30, 2024 (TW) 113116076
Nov. 14, 2024 (TW) 113143769
Aug. 11, 2025 (TW) 114130495
Oct. 13, 2025 (TW) 114139209

(51) Int. Cl. H01L 23/498; H01L 23/15

(52) U.S. Cl. CPC H01L 23/49827

(57) ABSTRACT

A substrate structure includes a first substrate and a second substrate bonded thereon. The first substrate includes a first dielectric substrate, a first conductive via, a first bonding layer, and a first electroless metal block. The first bonding layer has a first opening exposing the first conductive via, and the first electroless metal block is positioned within the first opening. The second substrate includes a second dielectric substrate, a second conductive via, a second bonding layer, and a second electroless metal block. The second bonding layer has a second opening exposing the second conductive via, and the second electroless metal block is positioned within the second opening. The second bonding layer is bonded to the first bonding layer to define a non-metal contact interface. The second electroless metal block is bonded to the first electroless metal block to define a metal bonding contact interface.

### CROSS-REFERENCE TO RELATED APPLICATION

This application is a continuation-in-part application of and claims the priority benefit of a prior application U.S. application Ser. No. 19/309,529, filed on Aug. 25, 2025, now pending. This application also claims the priority benefit of U.S. provisional application Ser. No. 63/836,407, filed on Jul. 1, 2025, and Taiwan application serial no. 114139209, filed on Oct. 13, 2025. The prior U.S. application Ser. No. 19/309,529 is a continuation-in-part application of and claims the priority benefit of a prior application U.S. application Ser. No. 19/023,397, filed on Jan. 16, 2025, now pending. The prior U.S. application Ser. No. 19/309,529 also claims the priority benefit of U.S. provisional application Ser. No. 63/699,160, filed on Sep. 26, 2024, and Taiwan application serial no. 114130495, filed on Aug. 11, 2025. The prior U.S. application Ser. No. 19/023,397 is a continuation-in-part application of and claims the priority benefit of U.S. application Ser. No. 18/677,924, filed on May 30, 2024, now pending. The prior U.S. application Ser. No. 19/023,397 also claims the priority benefit of U.S. provisional application Ser. No. 63/666,227, filed on Jun. 30, 2024, and Taiwan application serial no. 113143769, filed on Nov. 14, 2024. The prior U.S. application Ser. No. 18/677,924 also claims the priority benefit of U.S. provisional application Ser. No. 63/623,823, filed on Jan. 23, 2024, and Taiwan application serial no. 113116076, filed on Apr. 30, 2024. The entirety of each of the above-mentioned patent applications is hereby incorporated by reference herein and made a part of this specification.

### BACKGROUND

### Technical Field

The present invention relates to a substrate structure, and particularly relates to a substrate structure having better electrical reliability.

### Related Art

Currently, to fabricate through glass via (TGV) with high aspect ratio (AR) in glass substrates, two glass substrates are typically bonded through resin material, and the TGVs in the two glass substrates are electrically connected through conductive paste in the resin material. That is, after the two glass substrates are bonded, conductive paste exists between the two TGVs. However, after bonding, the conductive paste and the metal material in the TGVs may easily generate electrical discontinuity problems due to resistance variation, thereby affecting the electrical reliability of the formed substrate structure.

### SUMMARY

The present invention provides a substrate structure having better electrical reliability.

The substrate structure of the present invention includes a first substrate and a second substrate. The first substrate includes a first dielectric substrate, a first conductive via extending through the first dielectric substrate, a first bonding layer, and a first electroless metal block. The first bonding layer is configured on the first dielectric substrate and has a first opening exposing the first conductive via. The first electroless metal block is positioned within the first opening and electrically connected to the first conductive via. The second substrate includes a second dielectric substrate, a second conductive via extending through the second dielectric substrate, a second bonding layer, and a second electroless metal block. The second bonding layer is configured on the second dielectric substrate and has a second opening exposing the second conductive via. The second electroless metal block is positioned within the second opening and electrically connected to the second conductive via. The second substrate is bonded to the first substrate, the second bonding layer is bonded to the first bonding layer to define a non-metal contact interface, and the second electroless metal block is bonded to the first electroless metal block to define a metal bonding contact interface.

In an embodiment of the present invention, the opposite two ends of the first conductive via are aligned with the opposite two side surfaces of the first dielectric substrate. The opposite two ends of the second conductive via are aligned with the opposite two side surfaces of the second dielectric substrate.

In an embodiment of the present invention, a first opening diameter of the first opening is less than or equal to a first diameter of the first conductive via. A second opening diameter of the second opening is less than or equal to a second diameter of the second conductive via.

In an embodiment of the present invention, a ratio of the first opening diameter to the first diameter is between 0.25 and 1. A ratio of the second opening diameter to the second diameter is between 0.25 and 1.

In an embodiment of the present invention, the material of the first conductive via and the material of the second conductive via respectively include conductive paste.

In an embodiment of the present invention, the first conductive via and the second conductive via respectively include a seed layer and a conductive material configured on the seed layer.

In an embodiment of the present invention, the material of the first bonding layer and the material of the second bonding layer are organic polymer materials, for example, may respectively include polyimide-based materials or photo-imageable based materials.

In an embodiment of the present invention, the non-metal contact interface includes a covalent bonding contact interface or a thermoplastic adhesive contact interface.

In an embodiment of the present invention, the material of the first electroless metal block and the material of the second electroless metal block respectively include nano-twin copper (Nt-Cu).

In an embodiment of the present invention, the substrate structure includes at least one build-up structure layer configured on at least one of the first substrate and the second substrate, and electrically connected to at least one of the first conductive via and the second conductive via.

Based on the above, in the substrate structure of the present invention, the second bonding layer bonds to the first bonding layer to define the non-metal contact interface, and the second electroless metal block bonds to the first electroless metal block to define the metal bonding contact interface, such that the second substrate bonds to the first substrate, thereby forming a substrate structure having dielectric via(s) with high aspect ratios. Compared to the prior art, the present invention does not require additionally adding resin material having conductive paste and/or adopting glass substrates with high thickness, and may have advantages of simple process, reduced cost, and increased production capacity. Furthermore, since the substrate structure of the present invention does not require additionally adding resin material having conductive paste, the electrical continuity among the first conductive via, the first electroless metal block, the second electroless metal block, and the second conductive via enables the substrate structure of the present invention to have better electrical reliability.

To make the above features and advantages of the present invention more apparent and understandable, embodiments are specifically provided below and described in detail in conjunction with the accompanying drawings as follows.

### BRIEF DESCRIPTION OF THE DRAWINGS

FIG. 1A to FIG. 1I are cross-sectional schematic diagrams of a method for manufacturing a substrate structure according to an embodiment of the present invention.

FIG. 2 is a cross-sectional schematic diagram of a substrate structure according to an embodiment of the present invention.

FIG. 3 is a cross-sectional schematic diagram of a substrate structure according to another embodiment of the present invention.

FIG. 4 is a cross-sectional schematic diagram of a substrate structure according to another embodiment of the present invention.

### DESCRIPTION OF THE EMBODIMENTS

The embodiments of the present invention may be understood in conjunction with the drawings, and the drawings of the present invention are also considered as part of the disclosure. It should be understood that the drawings of the present invention are not drawn to scale, and in fact, the dimensions of elements may be arbitrarily enlarged or reduced to clearly illustrate the features of the present invention.

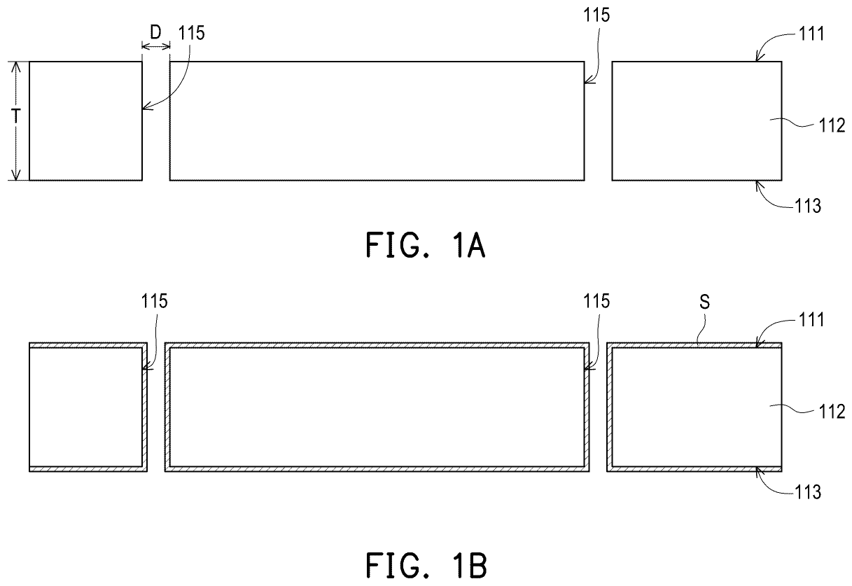

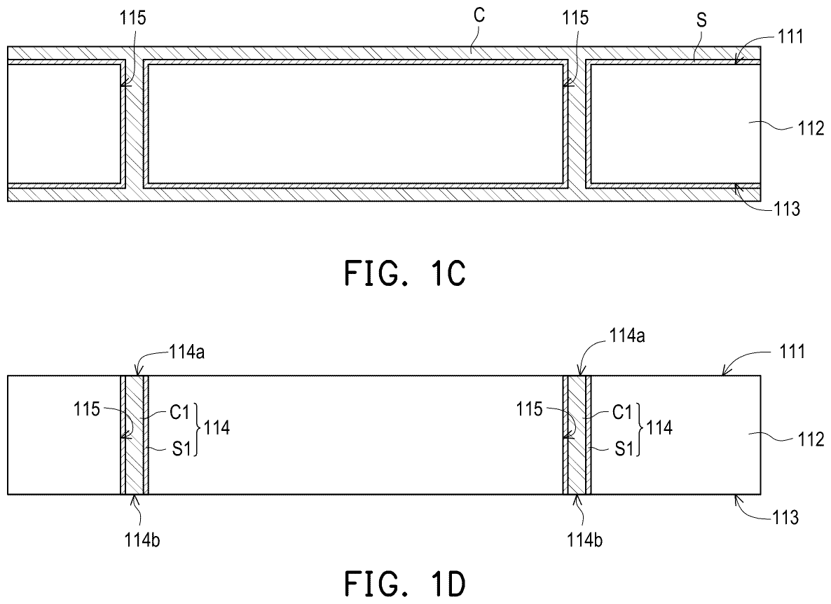

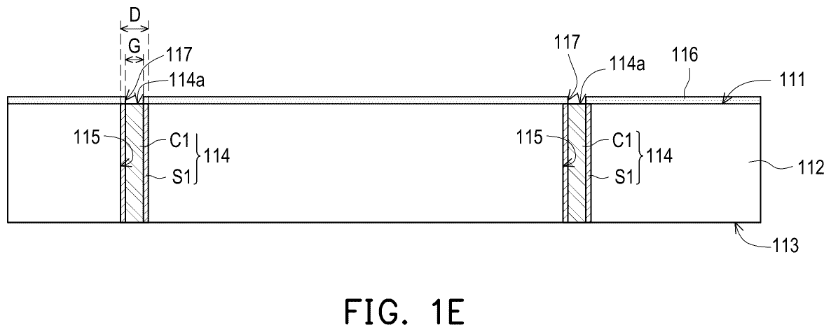

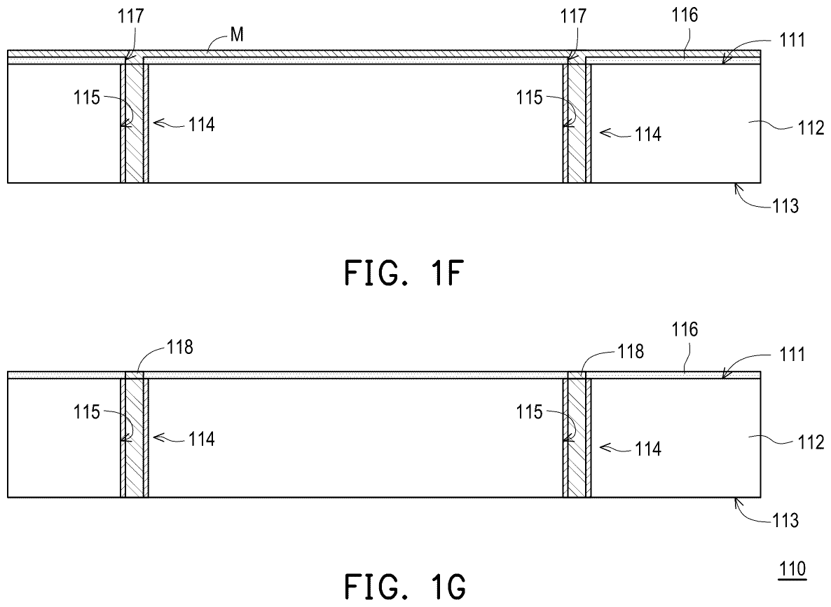

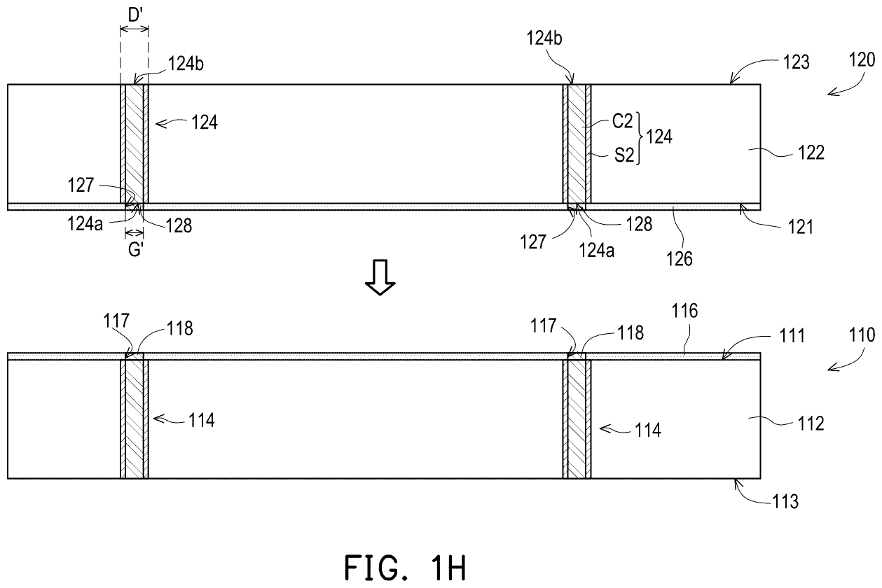

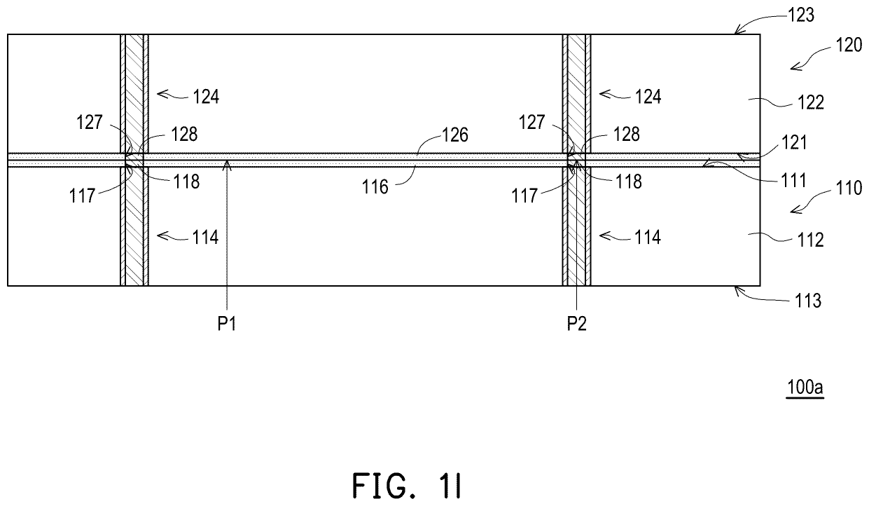

FIG. 1A to FIG. 1I are cross-sectional schematic diagrams of a method for manufacturing a substrate structure according to an embodiment of the present invention. According to the method for manufacturing a substrate structure of this embodiment, first, please refer to FIG. 1A, a first dielectric substrate 112 is provided. The first dielectric substrate 112 has an upper surface 111 and a lower surface 113 opposite to each other, and at least one through hole (two through holes 115 are schematically illustrated) extending through the first dielectric substrate 112. In one embodiment, the material of the first dielectric substrate 112 is, for example, an inorganic material, wherein the inorganic material is, for example, glass, ceramic, or glass-ceramic. In one embodiment, the material of the first dielectric substrate 112 is, for example, a non-conductive composite material. In one embodiment, the thickness T of the first dielectric substrate 112 is, for example, between 100 micrometers and 400 micrometers. In one embodiment, the surface roughness of the first dielectric substrate 112, such as arithmetic mean roughness (Ra), is less than 10 nanometers. In one embodiment, the through hole 115 may be a through glass via (TGV). In one embodiment, the first diameter D of the through hole 115 is, for example, 20 micrometers to 150 micrometers.

Next, please refer to FIG. 1B, a seed layer S is formed on the upper surface 111 and the lower surface 113 of the first dielectric substrate 112 and on the hole walls of the through holes 115 by a dry process (such as a sputtering process), or by a wet process (such as an electroless plating process), or by a hybrid process (including dry and wet processes). The seed layer S may provide a good interface so that metal layers subsequently formed thereon may adhere more easily, which may reduce the risk of detachment or peeling. In one embodiment, the material of the seed layer S is, for example, titanium-copper.

Next, please refer to FIG. 1C, using the seed layer S as an electroplating seed layer, a conductive material C is electroplated on the seed layer S. In one embodiment, the conductive material C directly covers the seed layer S and completely fills the through holes 115, wherein the conductive material C adheres tightly to the seed layer S. In one embodiment, the material of the conductive material C is, for example, copper. In one embodiment, the conductive material C may also be formed only within the through holes 115 and on the upper surface 111 of the first dielectric substrate 112, or only within the through holes 115 and on the lower surface 113 of the first dielectric substrate 112.

Next, please refer to FIG. 1C and FIG. 1D simultaneously, the conductive material C and the seed layer S thereunder located on the upper surface 111 and the lower surface 113 of the first dielectric substrate 112 are removed by, for example, a chemical-mechanical-polishing process (CMP), so as to completely expose the upper surface 111 and the lower surface 113 of the first dielectric substrate 112. At this time, the seed layer S1 and the conductive material C1 located within the through holes 115 define the first conductive vias 114. The first end 114a and the second end 114b of the first conductive vias 114 opposite to each other are respectively aligned with the upper surface 111 and the lower surface 113 of the first dielectric substrate 112. So far, the first conductive vias 114 extending through the first dielectric substrate 112 have been completed.

Next, please refer to FIG. 1E, a first bonding layer 116 is formed on the upper surface 111 of the first dielectric substrate 112 by, for example, a coating method. In one embodiment, the material of the first bonding layer 116 is an organic polymer material, which may be, for example, a polyimide-based material or a photo-imageable based material. In one embodiment, the first bonding layer 116 may be pre-cured or fully cured. In one embodiment, the first bonding layer 116 may be a thermoplastic material. Subsequently, first openings 117 are formed on the first bonding layer 116 by laser drilling or exposure, wherein the first openings 117 expose the first ends 114a of the first conductive vias 114. In one embodiment, a first opening diameter G of the first openings 117 is less than or equal to a first diameter D of the first conductive vias 114. In one embodiment, a ratio of the first opening diameter G to the first diameter D is, for example, between 0.25 and 1.

Next, please refer to FIG. 1F, an electroless metal layer M is formed on the outer surface of the first bonding layer 116 by electroless plating, wherein the electroless metal layer M completely covers the outer surface of the first bonding layer 116. In one embodiment, the material of the electroless metal layer M is, for example, nano-twin copper (Nt-Cu).

Next, please refer to FIG. 1F and FIG. 1G simultaneously, a portion of the electroless metal layer M is removed by, for example, a chemical-mechanical-polishing process (CMP), so as to form first electroless metal blocks 118 aligned with the first bonding layer 116. So far, the fabrication of the first substrate 110 has been completed.

Afterwards, please refer to FIG. 1H, a second substrate 120 is provided, wherein the structure of the second substrate 120 is the same as the structure of the first substrate 110, and may refer to the fabrication method of FIG. 1A to FIG. 1G described above. In brief, the second substrate 120 includes a second dielectric substrate 122, second conductive vias 124 extending through the second dielectric substrate 122, a second bonding layer 126, and second electroless metal blocks 128. The second conductive vias 124 include seed layers S2 and conductive materials C2 configured on the seed layers S2. First ends 124a and second ends 124b of the second conductive vias 124 opposite to each other are respectively aligned with an upper surface 121 and a lower surface 123 of the second dielectric substrate 122 opposite to each other. The second bonding layer 126 is configured on the second dielectric substrate 122 and has second openings 127 exposing the second conductive vias 124. In one embodiment, the material of the second bonding layer 126 is an organic polymer material, which may be, for example, a polyimide-based material or a photo-imageable based material. The second electroless metal blocks 128 are positioned within the second openings 127 and electrically connected to the second conductive vias 124. A second opening diameter G′ of the second openings 127 is less than or equal to a second diameter D′ of the second conductive vias 124. In one embodiment, a ratio of the second opening diameter G′ to the second diameter D′ is, for example, between 0.25 and 1. In one embodiment, the material of the second electroless metal blocks 128 is, for example, nano-twin copper (Nt-Cu).

Finally, please refer to FIG. 1H and FIG. 1I, the second substrate 120 is placed above the first substrate 110, so that the second bonding layer 126 faces the first bonding layer 116, and the second electroless metal blocks 128 are aligned with the first electroless metal blocks 118. Subsequently, the second substrate 120 and the first substrate 110 are bonded at high temperature (such as 150° C. to 250° C.) and high pressure (such as greater than one atmospheric pressure), wherein the second substrate 120 is bonded to the first substrate 110, the second bonding layer 126 is bonded to the first bonding layer 116 to define a non-metal contact interface P1, and the second electroless metal blocks 128 are bonded to the first electroless metal blocks 118 to define a metal bonding contact interface P2. In one embodiment, the non-metal contact interface P1 may be a covalent bonding contact surface, i.e., a chemical bonding contact surface formed by atoms sharing electrons. In one embodiment, the non-metal contact interface P1 may be a thermoplastic adhesive contact surface, i.e., a contact surface formed by intermolecular forces rather than chemical bonding forces. So far, the fabrication of the substrate structure 100a has been completed.

Structurally, please refer to FIG. 1I again, the substrate structure 100a includes the first substrate 110 and the second substrate 120. The first substrate 110 includes the first dielectric substrate 112, the first conductive via 114 extending through the first dielectric substrate 112, the first bonding layer 116, and the first electroless metal block 118. The first bonding layer 116 is configured on the first dielectric substrate 112 and has the first opening 117 exposing the first conductive via 114. The first electroless metal block 118 is positioned within the first opening 117 and electrically connected to the first conductive via 114. The second substrate 120 includes the second dielectric substrate 122, the second conductive via 124 extending through the second dielectric substrate 122, the second bonding layer 126, and the second electroless metal block 128. The second bonding layer 126 is configured on the second dielectric substrate 122 and has the second opening 127 exposing the second conductive via 124. The second electroless metal block 128 is positioned within the second opening 127 and electrically connected to the second conductive via 124. The second substrate 120 is bonded to the first substrate 110, the second bonding layer 126 is bonded to the first bonding layer 116 to define the non-metal contact interface P1, and the second electroless metal block 128 is bonded to the first electroless metal block 118 to define the metal bonding contact interface P2.

In brief, in this embodiment, the second bonding layer 126 may be bonded to the first bonding layer 116 through chemical bonding or intermolecular forces to define the non-metal contact interface P1, while the second electroless metal block 128 is bonded to the first electroless metal block 118 through metal diffusion to define the metal bonding contact interface P2, thereby bonding the second substrate 120 to the first substrate 110 to form the substrate structure 100a having dielectric through hole(s) with high aspect ratio. Compared to the prior art, this embodiment does not require additionally adding resin material having conductive paste and/or adopting glass substrate with high thickness, and may have advantages of simple process, reduced cost, and increased production capacity. Furthermore, since the substrate structure 100a of this embodiment does not require additionally adding resin material having conductive paste, the electrical continuity among the first conductive via 114, the first electroless metal block 118, the second electroless metal block 128, and the second conductive via 124 enables the substrate structure 100a of this embodiment to have better electrical reliability.

Other embodiments will be listed below for illustration. It must be noted that the following embodiments adopt the component reference numerals and partial content of the aforementioned embodiments, wherein the same reference numerals are used to represent the same or similar components, and the description of the same technical content is omitted. For the description of the omitted parts, reference may be made to the aforementioned embodiments, and the following embodiments will not be repeated redundantly.

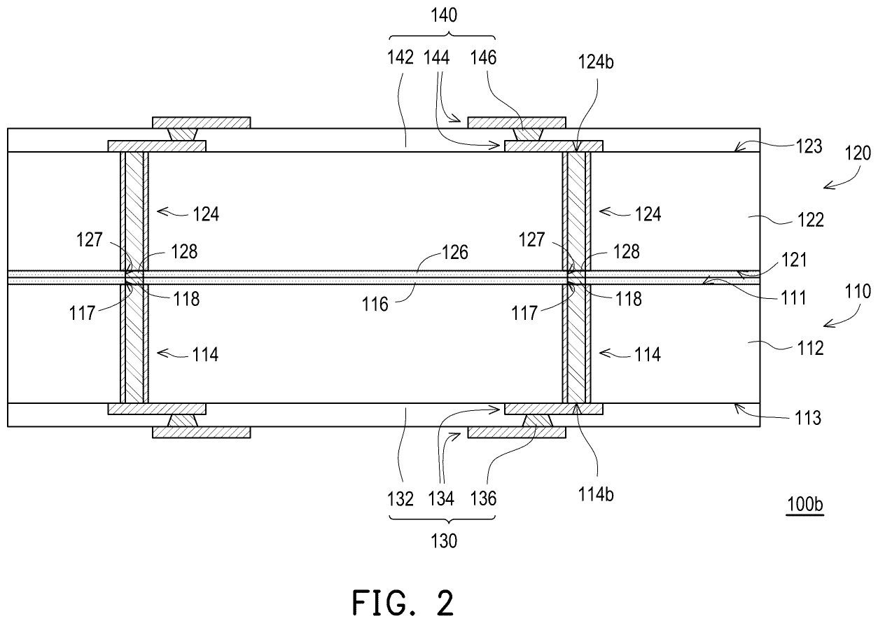

FIG. 2 is a cross-sectional schematic diagram of a substrate structure according to an embodiment of the present invention. Please refer to FIG. 1I and FIG. 2 simultaneously. The substrate structure 100b of this embodiment is similar to the substrate structure 100a of FIG. 1I described above, but the main difference between them is that: in this embodiment, the substrate structure 100b further includes at least one build-up structure layer configured on at least one of the first substrate 110 and the second substrate 120, and electrically connected to at least one of the first conductive via 114 and the second conductive via 124. Furthermore, the substrate structure 100b of this embodiment includes build-up structure layers 130, 140 respectively configured on the lower surface 113 of the first substrate 110 and the lower surface 123 of the second substrate 120, wherein the first substrate 110 and the second substrate 120 are located between the build-up structure layers 130, 140. In one embodiment, the build-up structure layers 130, 140 respectively include dielectric layers 132, 142, circuit layers 134, 144, and conductive blind vias 136, 146, wherein the dielectric layers 132, 142 and the circuit layers 134, 144 are alternately stacked, and the conductive blind vias 136, 146 connect the circuit layers 134, 144. In one embodiment, the circuit layers 134, 144 of the build-up structure layers 130, 140 are respectively electrically connected to the second end 114b of the first conductive via 114 and the second end 124b of the second conductive via 124.

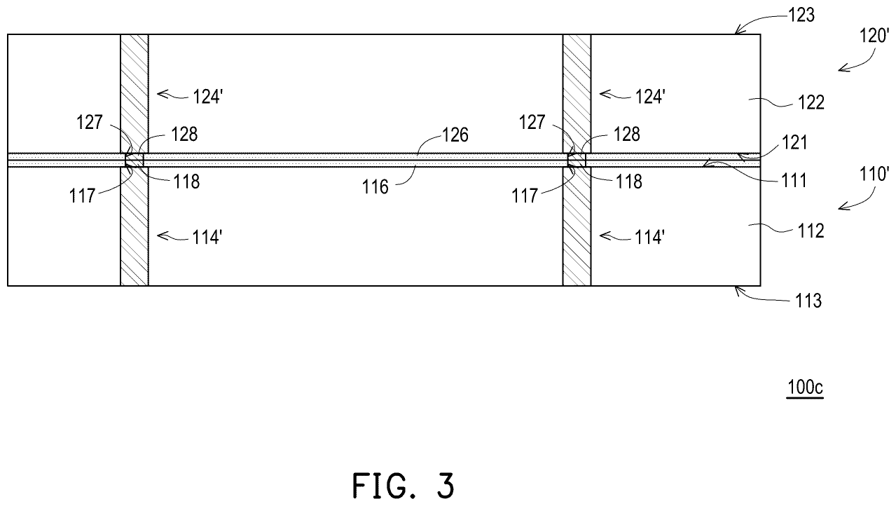

FIG. 3 is a cross-sectional schematic diagram of a substrate structure according to an embodiment of the present invention. Please refer to FIG. 1I and FIG. 3 simultaneously. The substrate structure 100c of this embodiment is similar to the substrate structure 100a of FIG. 1I described above, but the main difference between them is that: in this embodiment, the material of the first conductive via 114′ of the first substrate 110′and the material of the second conductive via 124′ of the second substrate 120′ are respectively conductive paste.

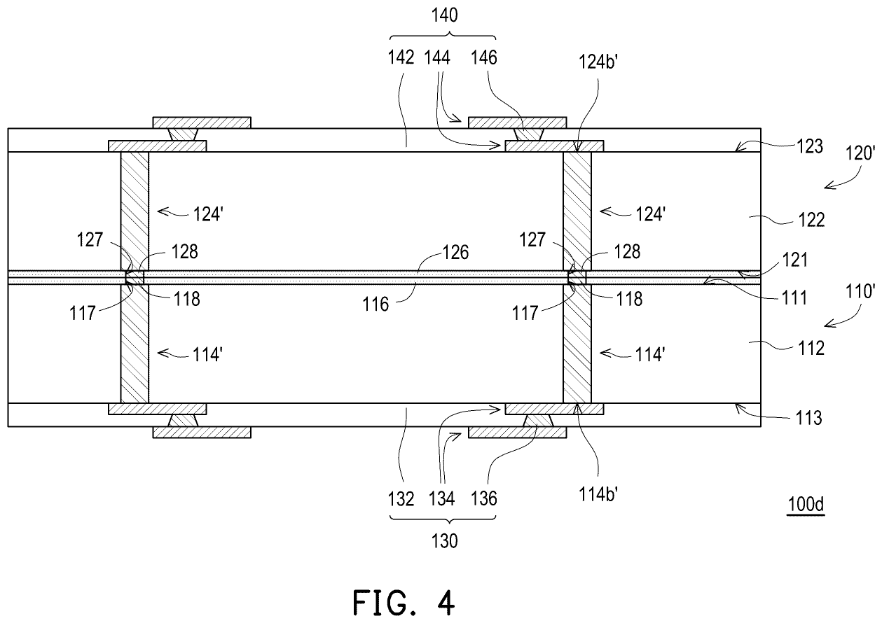

FIG. 4 is a cross-sectional schematic diagram of a substrate structure according to an embodiment of the present invention. Please refer to FIG. 3 and FIG. 4 simultaneously. The substrate structure 100d of this embodiment is similar to the substrate structure 100c of FIG. 3 described above, but the main difference between them is that: in this embodiment, the substrate structure 100d includes build-up structure layers 130, 140 respectively configured on the lower surface 113 of the first substrate 110′ and the lower surface 123 of the second substrate 120′, wherein the first substrate 110′ and the second substrate 120′ are located between the build-up structure layers 130, 140. In one embodiment, the build-up structure layers 130, 140 respectively include dielectric layers 132, 142, circuit layers 134, 144, and conductive blind vias 136, 146, wherein the dielectric layers 132, 142 and the circuit layers 134, 144 are alternately stacked, and the conductive blind vias 136, 146 connect the circuit layers 134, 144. In one embodiment, the circuit layers 134, 144 of the build-up structure layers 130, 140 are respectively electrically connected to the second end 114b′ of the first conductive via 114′ and the second end 124b′ of the second conductive via 124′.

In summary, in the substrate structure of the present invention, the second bonding layer bonds to the first bonding layer to define the non-metal contact interface, and the second electroless metal block bonds to the first electroless metal block to define the metal bonding contact interface, so that the second substrate bonds to the first substrate, thereby forming the substrate structure having dielectric through hole(s) with high aspect ratio. Compared to the prior art, the present invention does not require additionally adding resin material having conductive paste and/or adopting glass substrate with high thickness, and may have advantages of simple process, cost reduction, and increased production capacity. Furthermore, since the substrate structure of the present invention does not require additionally adding resin material having conductive paste, the electrical continuity between the first conductive via, the first electroless metal block, the second electroless metal block, and the second conductive via enables the substrate structure of the present invention to have better electrical reliability.

Although the present invention has been disclosed above with embodiments, they are not intended to limit the present invention. Any person having ordinary knowledge in the technical field may make slight modifications and refinements without departing from the spirit and scope of the present invention. Therefore, the protection scope of the present invention shall be defined by the appended claims.

What is claimed is:

1. A substrate structure, comprising:
a first substrate, comprising a first dielectric substrate, a first conductive via extending through the first dielectric substrate, a first bonding layer, and a first electroless metal block, the first bonding layer configured on the first dielectric substrate and having a first opening exposing the first conductive via, the first electroless metal block positioned within the first opening and electrically connected to the first conductive via; and
a second substrate, comprising a second dielectric substrate, a second conductive via extending through the second dielectric substrate, a second bonding layer, and a second electroless metal block, the second bonding layer configured on the second dielectric substrate and having a second opening exposing the second conductive via, the second electroless metal block positioned within the second opening and electrically connected to the second conductive via,
the second substrate bonded to the first substrate, the second bonding layer bonded to the first bonding layer to define a non-metal contact interface, and the second electroless metal block bonded to the first electroless metal block to define a metal bonding contact interface.

2. The substrate structure as claimed in claim 1, wherein opposite two ends of the first conductive via are aligned with opposite two side surfaces of the first dielectric substrate, and opposite two ends of the second conductive via are aligned with opposite two side surfaces of the second dielectric substrate.

3. The substrate structure as claimed in claim 1, wherein a first opening diameter of the first opening is less than or equal to a first diameter of the first conductive via, and a second opening diameter of the second opening is less than or equal to a second diameter of the second conductive via.

4. The substrate structure as claimed in claim 3, wherein a ratio of the first opening diameter to the first diameter is between 0.25 and 1, and a ratio of the second opening diameter to the second diameter is between 0.25 and 1.

5. The substrate structure as claimed in claim 1, wherein a material of the first conductive via and a material of the second conductive via respectively comprise conductive paste.

6. The substrate structure as claimed in claim 1, wherein the first conductive via and the second conductive via respectively comprise a seed layer and a conductive material configured on the seed layer.

7. The substrate structure as claimed in claim 1, wherein a material of the first bonding layer and a material of the second bonding layer respectively comprise organic polymer material.

8. The substrate structure as claimed in claim 1, wherein the non-metal contact interface comprises a covalent bonding contact surface or a thermoplastic adhesive contact surface.

9. The substrate structure as claimed in claim 1, wherein a material of the first electroless metal block and a material of the second electroless metal block respectively comprise nano-twin copper.

10. The substrate structure as claimed in claim 1, further comprising:
at least one build-up structure layer configured on at least one of the first substrate and the second substrate, and electrically connected to at least one of the first conductive via and the second conductive via.
